(19) United States
(12) Patent Application Publication
(10) Pub. No.: US 2018/0275173 A1
(43) Pub. Date: Sep. 27, 2018

(54) DEVICE AND METHOD FOR DETECTION OF ELECTRICAL CURRENT IN A BODY OF WATER

(71) Applicant: Not Real Shocking, LLC, Raleigh, NC (US)

(72) Inventor: W. Scott Hoffman, Raleigh, NC (US)

(73) Assignee: Not Real Shocking, LLC, Raleigh, NC (US)

(21) Appl. No.: 15/467,472

(22) Filed: Mar. 23, 2017

(51) Int. Cl. G01R 19/15; G08B 3/10; G08B 5/22; G08B 21/02

(52) U.S. Cl. CPC G01R 19/15; G08B 21/02; G08B 5/22; G08B 3/10

(57) ABSTRACT

The current invention relates to a device fixedly attached in a body of water such as a swimming pool for the detection of an unwanted electrical current in the water.

### COPYRIGHT NOTICE

A portion of the disclosure of this patent contains material that is subject to copyright protection. The copyright owner has no objection to the reproduction by anyone of the patent document or the patent disclosure as it appears in the Patent and Trademark Office patent files or records, but otherwise reserves all copyright rights whatsoever.

### BACKGROUND OF THE INVENTION

### Field of the Invention

The present invention relates the detection of electrical current in a body of water. In particular, it is a device and method for dangerous electrical current present in a body of water such as a swimming pool or lake, etc.

### Description of Related Art

The presence of an AC electrical current in bodies of water such as swimming pools, lakes and the like is responsible for a multitude of injuries and deaths around the world. Since the presence of the current is not visibly detectable and can occur suddenly due to a variety of conditions, the dangers of such conditions needs to be addressed.

It is not uncommon that an external electrical source can come in contact with water that puddles outside a body of water and or accidentally creates a linkage to current. While battery operated devices could be removably introduced to a body of water to check for current from time to time, the problems include batteries discharge or one can easily forget to engage a battery operated device or the device can easily be removed from the water and then just not used leaving the user unaware of a potential AC electrical current.

### BRIEF SUMMARY OF THE INVENTION

The present invention relates to a system for the detection of an electrical current in a swimming pool. The device is built into the pool drain or the pool metal ladder handrail and upon detection of an electrical current engages an alarm to warn people to get out of or not enter the body of water.

Accordingly, in one embodiment there is a body of water safety warning alert system for detection of the presence of an electrical current in the body of water comprising:
a) an electronic device that detects the presence of an AC current;
b) a mechanism for fixedly attaching the electronic device to a metal plumbing or a metal ladder in the body of water; and
c) an alarm which is triggered when the electronic device detects the presence of an electrical current in the body of water.

In another embodiment, there is a method for use in a body of water for detection of the presence of an electrical current in the body of water comprising:
a) fixedly attaching an electronic device that detects the presence of an AC current in the body of water where an electrical current can be detected in the body of water but where a user of the body of water cannot reach the device during use of the body of water; and
b) connecting an alarm to the electronic device which is triggered when the electronic device detects the presence of an electrical current in the body of water.

### BRIEF DESCRIPTION OF THE DRAWINGS

FIG. 1 is a relationship diagram of the system of the present invention.

FIG. 2 is the system of the present invention installed in a swimming pool as the body of water as well as depicts the method of the present invention.

FIG. 3 is an embodiment of a particular wiring diagram.

### DETAILED DESCRIPTION OF THE INVENTION

While this invention is susceptible to embodiment in many different forms, there is shown in the drawings and will herein be described in detail specific embodiments, with the understanding that the present disclosure of such embodiments is to be considered as an example of the principles and not intended to limit the invention to the specific embodiments shown and described. In the description below, like reference numerals are used to describe the same, similar or corresponding parts in the several views of the drawings. This detailed description defines the meaning of the terms used herein and specifically describes embodiments in order for those skilled in the art to practice the invention.

### Definitions

The terms “about” and “essentially” mean±10 percent.

The terms “a” or “an”, as used herein, are defined as one or as more than one. The term “plurality”, as used herein, is defined as two or as more than two. The term “another”, as used herein, is defined as at least a second or more. The terms “including” and/or “having”, as used herein, are defined as comprising (i.e., open language). The term “coupled”, as used herein, is defined as connected, although not necessarily directly, and not necessarily mechanically.

The term “comprising” is not intended to limit inventions to only claiming the present invention with such comprising language. Any invention using the term comprising could be separated into one or more claims using “consisting” or “consisting of” claim language and is so intended.

Reference throughout this document to “one embodiment”, “certain embodiments”, and “an embodiment” or similar terms means that a particular feature, structure, or characteristic described in connection with the embodiment is included in at least one embodiment of the present invention. Thus, the appearances of such phrases or in various places throughout this specification are not necessarily all referring to the same embodiment. Furthermore, the particular features, structures, or characteristics may be combined in any suitable manner in one or more embodiments without limitation.

The term “or” as used herein is to be interpreted as an inclusive or meaning any one or any combination. Therefore, “A, B or C” means any of the following: “A; B; C; A and B; A and C; B and C; A, B and C”. An exception to this definition will occur only when a combination of elements, functions, steps or acts are in some way inherently mutually exclusive.

The drawings featured in the figures are for the purpose of illustrating certain convenient embodiments of the present invention, and are not to be considered as limitation thereto. Term “means” preceding a present participle of an operation indicates a desired function for which there is one or more embodiments, i.e., one or more methods, devices, or apparatuses for achieving the desired function and that one skilled in the art could select from these or their equivalent in view of the disclosure herein and use of the term “means” is not intended to be limiting.

As used herein the term “body of water” refers to a pond, lake, river, swimming pool or the like for swimming, bath, wading, or other water activities. In the case of pools, pools can be built into the ground (inground pools) or built above ground (as a freestanding construction or as part of a building or other larger structure), and are also a standard feature aboard ocean liners and cruise ships. Inground pools are most commonly constructed from materials such as concrete, natural stone, metal, plastic or fiberglass, and can be of a custom size and shape or built to a standardized size, the largest of which is the Olympic-size swimming pool. Deep pools usually are provided with a ladder to enter the pool which is generally made of stainless steel or other corrosion resistant metal. Lakes, ponds and the like are either natural or man-made and frequently have man-made features such as a dock, ladder or the like.

As used herein the term “safety warning alert” or “alarm” refers to a device which makes a user of a body of water aware that there is an electrical current in the water. This can be an audio alarm such as a siren, voice announcement, or the like. It can also be a visual alert such as a flashing light, a sign that illuminates or the like. It could also involve some tactile announcement to alert an individual who announces clearance of the pool like a lifeguard or any other means for letting swimmers know they need to leave the pool. In general, the safety alert is triggered by the electronic device detecting an electrical current in the swimming pool. In one embodiment, the signal to activate the alarm is sent from the electronic device by the microprocessor wirelessly. Information to a monitor or monitor station could also be sent wirelessly but of course could be done in a wired manner. The monitor could check for actual current, if any at any time, rather than waiting or relying on the alarm. In one embodiment, there is an indicator light on the alarm to indicate it is powered and working.

As used herein the term “detection of the presence of an electrical current” refers to the detection of an AC current in the swimming pool water sufficient to injure or kill a user of the swimming pool in contact with the water in the pool.

As used herein the term “electronic device” refers to a device designed to detect the presence of an AC electrical current in water. Such devices are known and can be powered by the presence of the current being measured or self-powered by AC or DC current such as electrical connection or batteries. The device can be analog or digital but must have the capacity to send a signal when there is the presence of an electrical current. In one embodiment, a microprocessor is utilized to control the function of the electronic device, the alarm and any other device utilized with the system. When the electronic device detects the electrical current, the alarm is then activated. The electronic device may, in one embodiment, have an indicator light to indicate the device is on. The device is fixed to something conducting, and in one embodiment, attached where it is not reachable by the person in the water such as in a metal ladder, a drain or the like.

As used herein the term “mechanism for fixedly attaching the electronic device” refers to the system being attached to the pool in some fixed (i.e. not easily removable) manner. A device that is set in the water or can be easily removed by those using a pool is not within the scope of this invention.

In one embodiment, the device is positioned fixedly (screws, brackets, clamps or the like) in the drain or the pool ladder. If the ladder is metal, placing it in contact with the metal ladder anywhere, even outside the pool water, will work since the pool ladder could conduct the electricity to be measured. In one embodiment, the device is fixedly attached inside the pool ladder or inside the drain to make it next to impossible to remove the device.

As used herein the term “drain or plumbing” refers to the standard bottom drain in a swimming pool or any of the plumbing associated with the body of water.

As used herein the term “metal pool ladder” refers to a stainless steel or other electrical conducting metal device i.e. a ladder for getting in and out of a swimming pool.

As used herein the term “the method of the present invention” refers to a method for use in a swimming pool for detection of the presence of an electrical current in the swimming pool water in the swimming pool comprising positioning an electronic device that detects the presence of an AC current in the swimming pool where an electrical current can be detected in the swimming pool water but where a user of the pool cannot reach the device during use of the pool and connecting an alarm to the electronic device which is triggered when the electronic device detects the presence of an electrical current in the swimming pool water.

### DRAWINGS

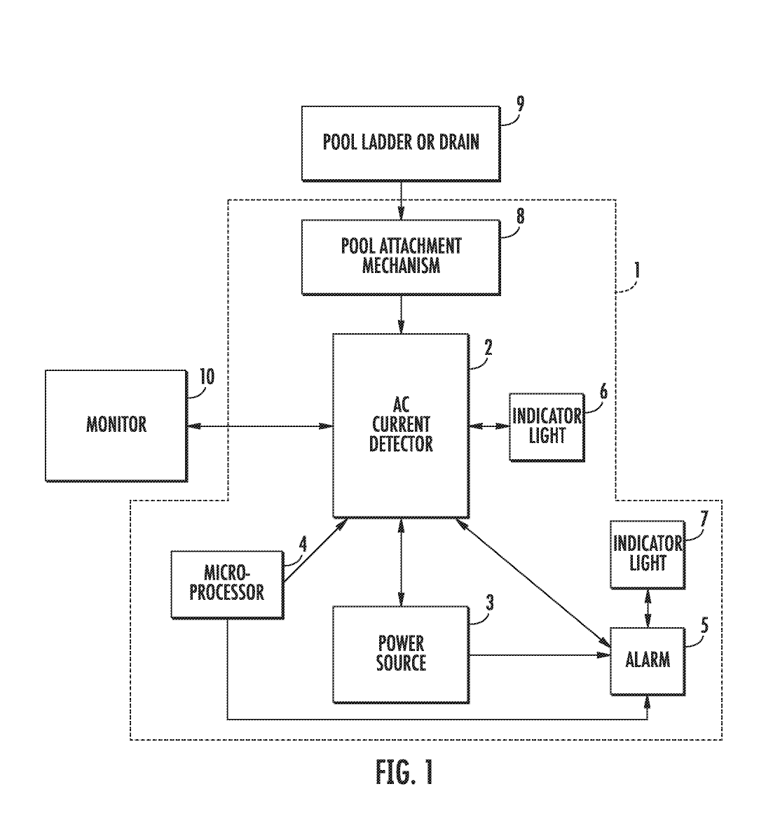

Now referring to the drawings. FIG. 1 is a relationship diagram of the present invention. The safety warning alert system for detection of the presence of an electrical current in water (in this embodiment a swimming pool) 1 consists of AC current detector 2 which can be self-powered or have an external power source 3. A microprocessor 4, where used, can control the current detector and activate the alarm 5 (which can also directly interact with alarm if desired). The AC current detector 2 can also have an indicator light 6 indicating it is powered. The alarm 5 can also have an indicator light 7. The AC current detector 2 is fixedly attached to the pool by the pool attachment mechanism 8, for example the pool ladder or drain 9. In an additional embodiment, the AC current detector 2 can be accessed and read from an external monitor 10.

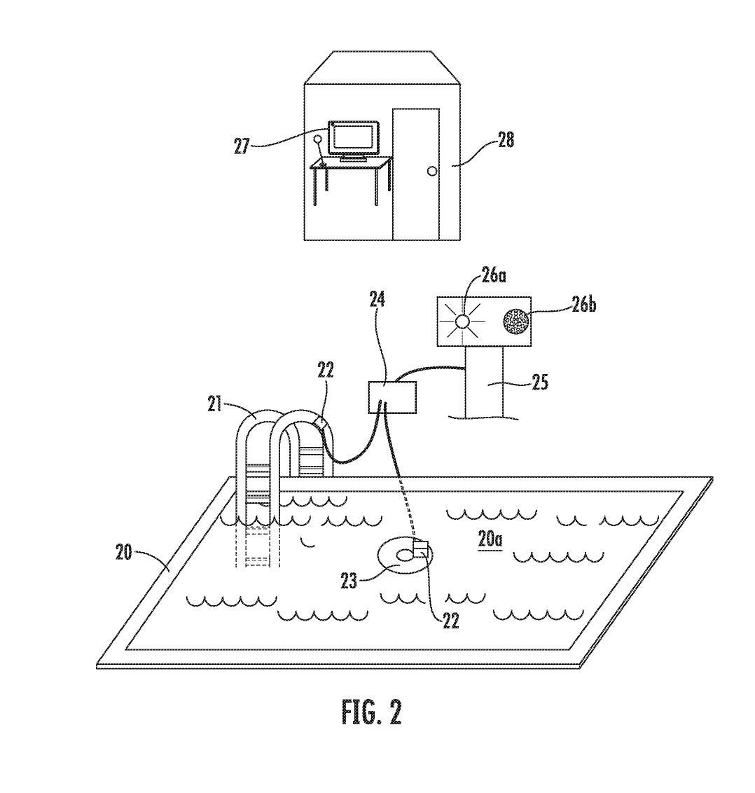

FIG. 2 depicts the system of the present invention in use. In this perspective view, swimming pool 20 has water 20a. Stainless steel ladder 21 goes from outside of the pool water 20a to inside of the pool water 20a. In this view, the electronic device 22 is positioned on the inside of the railing of the stainless steel ladder 21 outside of the pool water 20a (but could be inside of the pool water 20a on the stainless steel ladder 21 or inside (or outside) the pool drain 23). Upon detecting an electrical current, the microprocessor 24 receives the signal from the electronic device 22 and turns alarm 25 on which has alarm light 26a and sound alarm 26b. In an optional embodiment, the microprocessor 24 sends information on the electronic device wirelessly (thought could be wired) to monitor 27 in pool house 28.

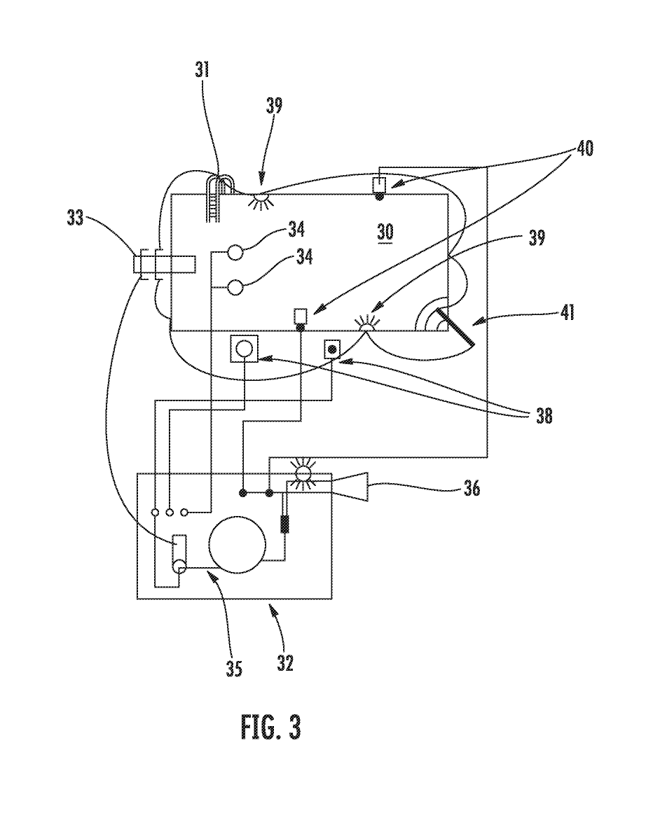

FIG. 3 is an embodiment of the present invention wherein swimming pool 30 with stainless steel ladder 31, pool house 32 and diving board 33. Also shown are plumbing drains 34. Pool house 32 is outfitted with AC current detector 35 and audio alarm 36. AC current detector 35 is wired by the various metal locations/items for detecting current. Also shown are pool skimmers 38, pool light 39, and pool return 40. In this wiring diagram, pool handrail 41 is shown wired to the system.

Those skilled in the art to which the present invention pertains may make modifications resulting in other embodiments employing principles of the present invention without departing from its spirit or characteristics, particularly upon considering the foregoing teachings. Accordingly, the described embodiments are to be considered in all respects only as illustrative, and not restrictive, and the scope of the present invention is, therefore, indicated by the appended claims rather than by the foregoing description or drawings. Consequently, while the present invention has been described with reference to particular embodiments, modifications of structure, sequence, materials and the like apparent to those skilled in the art still fall within the scope of the invention as claimed by the applicant.

What is claimed is:

1. A body of water safety warning alert system for detection of the presence of an electrical current in the body of water comprising:
a) an electronic device that detects the presence of an AC current;
b) a mechanism for fixedly attaching the electronic device to a metal plumbing or a metal ladder in the body of water; and
c) an alarm which is triggered when the electronic device detects the presence of an electrical current in the body of water.

2. The system according to claim 1 wherein the alarm is selected from the group consisting of an audio alarm and a visual alarm.

3. The system according to claim 1 wherein the alarm detects the electronic device wirelessly.

4. The system according to claim 1 wherein the body of water is a swimming pool.

5. The system according to claim 4 wherein the electronic device is positioned on the pool ladder outside the water and detects the current conducted from the water through the metal ladder to the detection device.

6. The system according to claim 1 wherein the electronic device can transmit the detection of the presence of an AC electrical current wirelessly.

7. The system according to claim 1 wherein the electronic device can send information to a user of the system on demand regarding the presence of an electrical current.

8. The system according to claim 1 wherein at least one of the alarm and electronic device is AC powered.

9. The system according to claim 1 wherein there is a power indicator light on at least one of the electronic device or the alarm.

10. The system according to claim 5 wherein the electronic device is positioned inside the pool ladder or pool drain.

11. A method for use in a body of water for detection of the presence of an electrical current in the body of water comprising:
a) fixedly attaching an electronic device that detects the presence of an AC current in the body of water where an electrical current can be detected in the body of water but where a user of the body of water cannot reach the device during use of the body of water; and
b) connecting an alarm to the electronic device which is triggered when the electronic device detects the presence of an electrical current in the body of water.

12. The method according to claim 11 wherein the body of water is a swimming pool.

13. The method according to claim 12 wherein the electronic device is positioned in either a swimming pool ladder, or in a swimming pool drain, or in a swimming pool plumbing.
